(19) United States
(12) Patent Application Publication
(10) Pub. No.: US 2006/0071284 A1
(43) Pub. Date: Apr. 6, 2006

(54) Easily crack checkable semiconductor device

(75) Inventors: Akira Tai, Okazaki-city (JP); Yoshiaki Nakayama, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/239,088

(22) Filed: Sep. 30, 2005

(30) Foreign Application Priority Data
Oct. 1, 2004 (JP) 2004-290119

(51) Int. Cl. H01L 29/76

(52) U.S. Cl. 257/379

(57) ABSTRACT

A semiconductor device includes a first insulation film, a second insulation film, a thin film resistor interposed between the insulation films. A predetermined voltage is applied to the thin film resistor so that a current flows through the thin film resistor. When a crack occurs in the insulation films, the thin film resistor is partially destroyed and the resistance of the thin film resistor changes. The crack is detected by measuring the change in resistance of the thin film resistor based on the predetermined voltage and the current flowing through the thin film resistor. Therefore, a crack inspection can be conducted without destruction of the device.

### CROSS REFERENCE TO RELATED APPLICATION

This application is based on Japanese Patent Application No. 2004-290119 filed on Oct. 1, 2004, the disclosure of which is incorporated herein by reference.

### FIELD OF THE INVENTION

The present invention relates to a semiconductor device, to which a crack inspection can easily apply.

### BACKGROUND OF THE INVENTION

In a manufacturing process of a semiconductor device, an inspection for detection of a crack is conducted. The crack typically occurs in an interlayer insulation film of the semiconductor device during a wire bonding process, a packaging process, or an endurance test. In the method used for the crack detection, the chip surface of the device is visually inspected, because a semiconductor element is disposed on the chip surface. Therefore, the chip surface is required to be exposed by disassembling the package or disconnecting the wiring.

It takes much time and effort to detect the crack using the visual inspection method. Further, the device may be broken after the visual inspection. Therefore, the visual inspection is applied to only some of the manufactured devices, not all of the manufactured devices. In other words, the visual inspection is a sampling inspection, not a 100% inspection. Therefore, it is impossible to detect cracks in all of the manufactured devices by means of the visual inspection. The quality of the devices is not fully ensured, as a result.

In semiconductor manufacturing industry, there is an increasing demand that the problems of the visual inspection should be solved. JP-A-2004-53326 refers to the demand.

### SUMMARY OF THE INVENTION

In view of the above-described problem, it is an object of the present invention to provide a semiconductor device to which a crack inspection can apply without destruction of the device.

A semiconductor device includes a first interlayer insulation film, a second interlayer insulation film, a thin film resistor interposed between the first and the second interlayer insulation films, a first electrode pad connected to the thin film resistor, and a second electrode pad connected to the thin film resistor. A predetermined voltage is applied to the thin film resistor using the first and the second electrode pad so that an electric current flows through the thin film resistor. When a crack occurs in the first interlayer insulation film or the second interlayer insulation film, the thin film resistor is at least partially destroyed. Accordingly, the resistance of the thin film resistor changes and the amount of the current changes.

Therefore, the crack can be detected by calculating the change in resistance of the thin film resistor based on the predetermined voltage applied to the thin film resistor and the current flowing through the thin film resistor.

The thin film resistor is thus used for detecting a crack. The crack can be detected by passing the current through the thin film resistor using the pads and measuring the resistance of the thin film resistor. Therefore, the crack inspection can be conducted during various stages in the manufacturing process of the semiconductor device.

The crack inspection can be conducted without disassembling the package or disconnecting the wiring, i.e., without destruction of the device. Therefore, not only a sampling inspection, but also a 100% inspection can be applied to the device. Accordingly, the quality of the device increases.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross section view showing a semiconductor device according to a first embodiment of the present invention;

FIG. 2 is a plan view showing a layout of a thin film resistor and electrode pads connected to the thin film resistor of the device shown in FIG. 1;

FIGS. 3A and 3B are cross section views showing a relationship between a thickness of the thin film resistor and a flatness of an interlayer insulation film;

FIG. 4 is a flow diagram illustrating a manufacturing process of the device shown in FIG. 1;

FIG. 5 is a graph showing a relationship between the number of disconnected lines of the thin film resistor and resistance of the thin film resistor;

FIG. 6 is a cross section view showing a semiconductor device according to a second embodiment of the present invention, and

FIG. 7 is a plan view showing a layout of a thin film resistor of the device shown in FIG. 6.

### DETAILED DESCRIPTION OF THE PREFERRED EMBODIMENTS

### First Embodiment

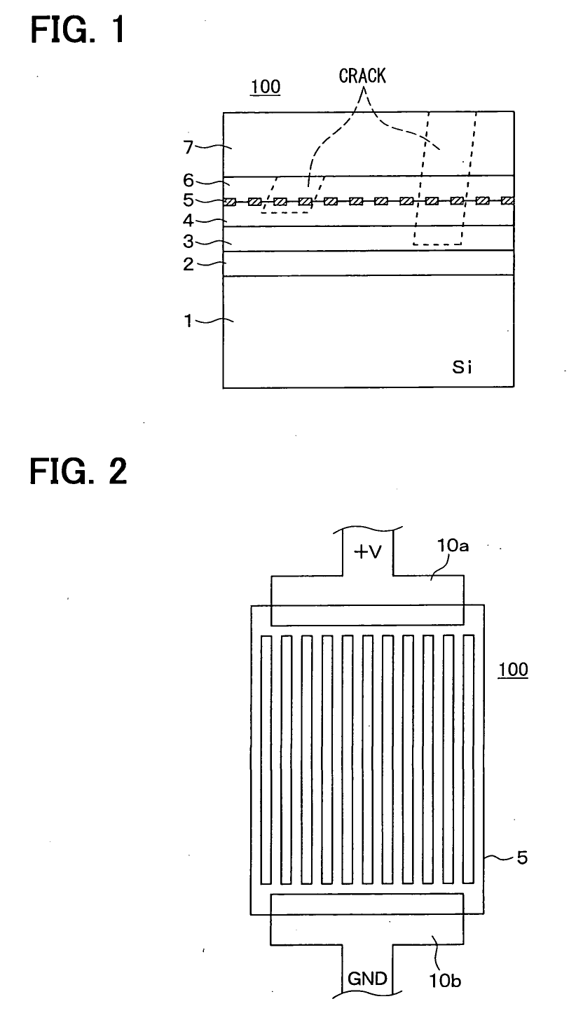

A semiconductor device 100 according to a first embodiment of the present invention is shown in FIGS. 1 and 2. The device 100 includes a silicon substrate 1, a field oxide film 2 disposed on the substrate 1, a boron-doped phosphor-silicate glass (BPSG) film 3 disposed on the field oxide film 2, a first tetraethylorthosilicate (TEOS) film 4 disposed on the BPSG film 3, a thin film resistor 5 disposed on the first TEOS 4, a second TEOS film 6 disposed on the thin film resistor 5, and a protective film 7 disposed on the second TEOS film 6.

Specifically, the thin film resistor 5 is disposed on a surface of the first TEOS film 4 as a first insulation film, after the field oxide film 2, the BPSG film 3, and the first TEOS film 4 are stacked in this order on the substrate 1. Then, the second TEOS film 6 as a second insulation film covers the thin film resistor 5, and the protective film 7 covers a surface of the second TEOS film 6.

Disposing the thin film resistor 5 on the top layer of the substrate 1 makes the stacked structure of the device 100, after a wiring pattern is formed on the substrate 1 on which a semiconductor element is formed.

The thin film resistor 5 has multiple line portions in the midsection and has flat portions at both ends so that a stripe pattern appears on the thin film resistor 5. Each line portion merges into both ends of the thin film resistor 5. One end of the thin film resistor 5 is electrically connected to the electrode pad 10a to which a predetermined voltage is applied. The other end of the thin film resistor 5 is electrically connected to the electrode pads 10b connected to ground (GND).

At least one thin film resistor 5 is disposed on each device 100 formed on the substrate 1. Thus, the device 100 has at least one thin film resistor 5 after the substrate 1 is divided into individual chips of the device 100 by a dicing process.

The thin film resistor 5 is interposed between the first TEOS film 4 and the second TEOS film 6, i.e., between interlayer insulation films. Therefore, the thin film resistor 5 can be disposed at any position in the device 100.

For example, the thin film resistor 5 may be disposed to overlap an area where the semiconductor element is formed. Alternatively, the thin film resistor 5 may be disposed over a metal wiring layer such as an aluminum wiring layer, under a wire bonding area, or around a corner portion of the chip of the device 100.

The line portions of the thin film resistor 5 have a width of 1 micrometer, for example. The thin film resistor 5 has a thickness between 5 nanometers and 500 nanometers, for example. The thickness between 5 nanometers and 500 nanometers is comparatively thin so that the flatness of the second TEOS film 6 can be maintained.

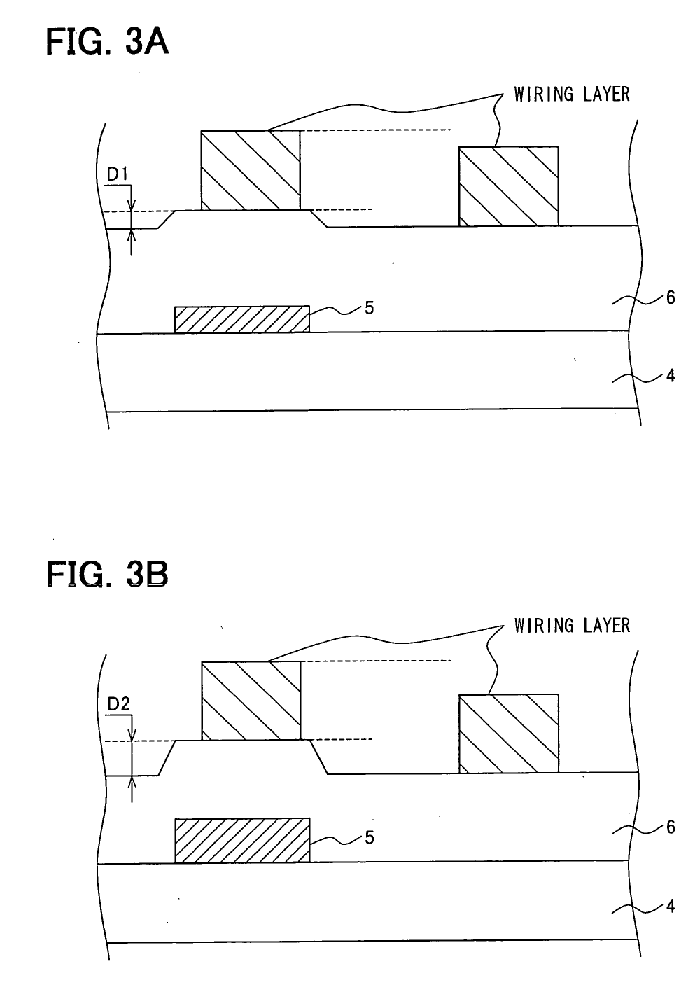

FIGS. 3A and 3B show a relationship between the thickness of the thin film resistor 5 and the flatness of the second TEOS film 6. FIG. 3A represents the case when the thin film resistor 5 has a first thickness between about 5 nanometers and 500 nanometers, and FIG. 3B represents the case when the thin film resistor 5 has a second thickness larger than the first thickness. When the thin film resistor 5 has the first thickness, the second TEOS film 6 has a first height difference D1. In contrast, when the thin film resistor has the second thickness, the second TEOS film 6 has a second height difference D2. The first thickness is smaller than the second thickness so that the first height difference D1 becomes smaller than the second height difference D2.

Therefore, an etching area to form a wiring layer disposed on the second TEOS film 6 can be reduced by adjusting the thickness of the thin film resistor 5 to the first thickness, i.e., between about 5 nanometers and 500 nanometers. Thus, a margin for processing the wiring layer increases and the wiring layer can be easily formed. Preferably, the thickness of the thin film resistor 5 is adjusted between 5 nanometers and 50 nanometers, because a wide margin for processing the wiring layer is provided.

Any resistor material can be used as a material for forming the thin film resistor 5. For example, the thin film resistor can be made of aluminum (Al), aluminum silicon (AlSi), aluminum silicon copper (AlSiCu), polysilicon (PolySi), titanium (Ti), titanium nitride (TiN), tungsten silicide (Wsi), titanium silicide (TiSi), chromium (Cr), cupper (Cu), nickel (Ni), cobalt (Co), or gold (Au).

The chip of the device 100 is sealed in a resin package (not shown). The semiconductor element and the thin film resistor 5 formed on the device 100 are electrically connected to an external device through terminals (not shown) drawn out of the resin package.

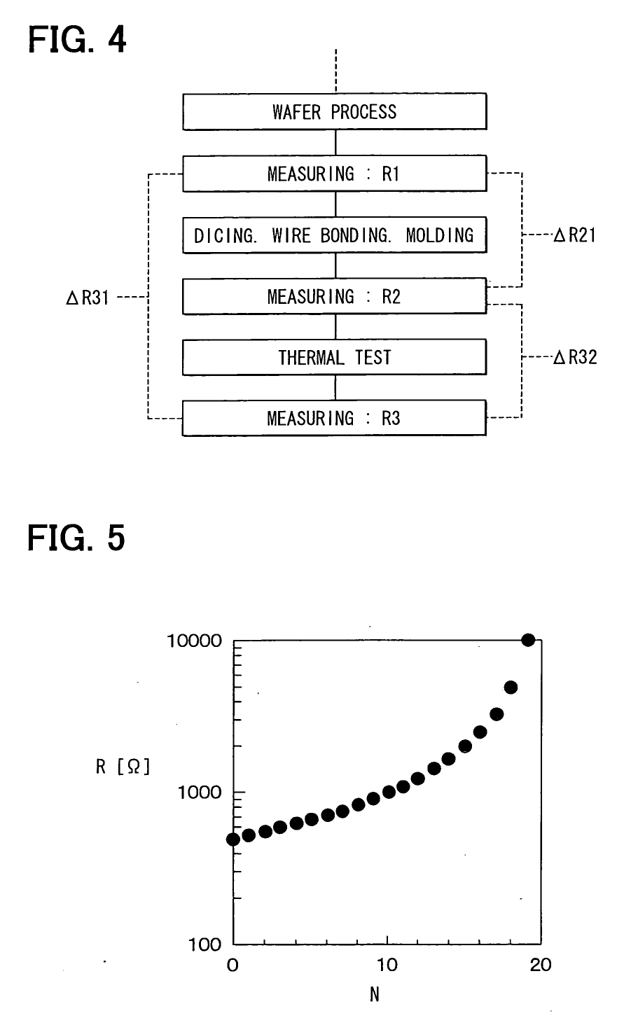

Manufacturing processes of the device 100 will be described with reference to FIG. 4, which shows a flow diagram of the manufacturing process.

The manufacturing processes start with forming the semiconductor element on the substrate 1, and then a wafer process is applied to the substrate 1. During the wafer process, the field oxide film 2, the BPSG film 3, the first TEOS film 4, the thin film resistor 5, the second TEOS film 6, and the protective film 7 are formed on the substrate 1.

Specifically, the semiconductor element is formed on the substrate 1 by means of a well-known semiconductor manufacturing process. The field oxide film 2 is also formed on the substrate 1 while the semiconductor element is formed.

The BPSG film 3 is deposited on the field oxide film 2 and a contact hole is formed in the BPSG film 3. Then, a first aluminum-wiring layer (not shown) is deposited on the surface of the BPSG film 3 and formed into a predetermined wiring pattern. A predetermined diffusion layer of the semiconductor element and the first aluminum-wiring layer are electrically connected through the contact hole.

The first TEOS film 4 is deposited on the surface of the BPSG film 3. Then, a resistor material is deposited on the surface of the first TEOS film 4 and formed into a predetermined pattern of the thin film resistor 5.

The second TEOS film 6 is deposited on the surface of the thin film resistor 5 and the first TEOS film 4. A via hole (not shown) is formed in the first TEOS film 4 and the second TEOS film 6.

Then, a second aluminum-wiring layer (not shown) is deposited on the surface of the second TEOS film 6 and formed into a predetermined wiring pattern. The protective film 7 is formed on the surface of the second aluminum wiring layer and the second TEOS film 6. Then, opening portions are formed in the protective film 7 so that the electrode pads 10a, 10b can be exposed to the surface of the protective film 7 through the opening portions. Thus, the semiconductor device 100 is manufactured.

A first resistance R1 of the thin film resistor 5 is measured as a initial resistance, after the wafer process is finished. The predetermined voltage is applied between the electrode pads 10a and the electrode pad 10b, thereby passing a current through the thin film resistor 5. The first resistance R1 is determined based on the current and the voltage.

As of after the wafer process, it may be assumed that the thin film resistance 5 is not broken, because the wafer process seldom cause the crack in the first TEOS film 4 or the second TEOS film 6. Therefore, the first resistance R1 can be used as a reference resistance.

A dicing process and a wire bonding process follow the wafer process. Then, the device 100 is molded with the resin package during a packaging process, thereby completing the chip of the device 100.

A second resistance R2 is measured in the same way as the first resistance measurement, after the packaging process is finished. However, the electrode pads 10a, 10b may be covered with the resin package after the packaging process. In this case, the terminals electrically connected to the electrode pads 10a, 10b are drawn out of the resin package so that the predetermined voltage can be applied between the electrode pads 10a, 10b through the terminals.

After the packaging process, it may be assumed that there is a crack in the first TEOS film 4 or the second TEOS film 6, because the crack is introduced into the device 100 in the dicing process, the wire bonding process, and the packaging process.

When cracks shown in FIG. 1 occur, some lines of the thin film resistor 5 are disconnected or partially broken. As a result, the second resistance R2 becomes different from the first resistance R1, and accordingly the amount of the current flowing through the thin film resistor 5 changes. A resistance difference ΔR21 is determined by subtracting the first resistance R1 from the second resistance R2. It can be determined whether cracks occur, based on the magnitude of the resistance difference ΔR21. Further, the number of the cracks can be determined based on the magnitude of the resistance difference ΔR21, if the crack occurs.

FIG. 5 shows a relationship between the number N of the disconnected lines of the thin film resistor 5 and the resistance R of the thin film resistor 5. In the example shown in FIG. 5, the thin film resistor 5 has twenty lines. Each line has a resistance of 10 kilo-ohms and a width of 1 micrometer. A space between two neighboring lines is 1 micrometer. As long as the second resistance R2 of the thin film resistor 5 is determined, the number N of the disconnected lines of the thin film resistor 5 can be determined based on the relationship in FIG. 4. Further, the number of the cracks can be determined based on the number N of the disconnected lines of the thin film resistor 5.

After the second resistance R2 is measured, a thermal cycle test is applied to the device 100. During one cycle of the thermal cycle test, the device 100 is cooled to a predetermined temperature after being heated to another predetermined temperature. The cycle is repeated by a predetermined number of times.

After the thermal cycle test is finished, a third resistance R3 of the thin film resistor 5 is measured in the same way as the second resistance R2.

After the thermal cycle test, it may be assumed that new crack occurs in the first TEOS film 4 or the second TEOS film 6, because new crack is introduced into the device 100 in the thermal cycle test. That is why the third resistance R3 is measured after the thermal cycle test. A resistance difference ΔR31 is determined by subtracting the first resistance R1 from the third resistance R3. Likewise, a resistance difference ΔR32 is determined by subtracting the second resistance R2 from the third resistance R3. It can be determined whether cracks occur, based on the magnitudes of the resistance differences ΔR31, ΔR32. The number of the cracks can be also determined based on the magnitudes of the resistance differences ΔR31, ΔR32, if the crack occurs.

Thus, the crack inspection can be conducted during the manufacturing process of the device 100. It is determined by the crack inspection not only whether the crack occurs but also how many cracks occur.

As described above, the device 100 has the thin film resistor 5 interposed between the first TEOS film 4 and the second TEOS film 6, i.e., between the interlayer insulation films. The thin film resistor 5 is used for detecting the crack. The crack inspection can be conducted during various stages in the manufacturing process of the device 100, because the crack can be detected by measuring the resistance of the thin film resistor 5.

The crack inspection can be conducted without disassembling the package or disconnecting the wiring, i.e., without destruction of the device 100. Therefore, not only a sampling inspection, but also a 100% inspection can be applied to the device 100. The quality of the device 100 increases accordingly.

### Second Embodiment

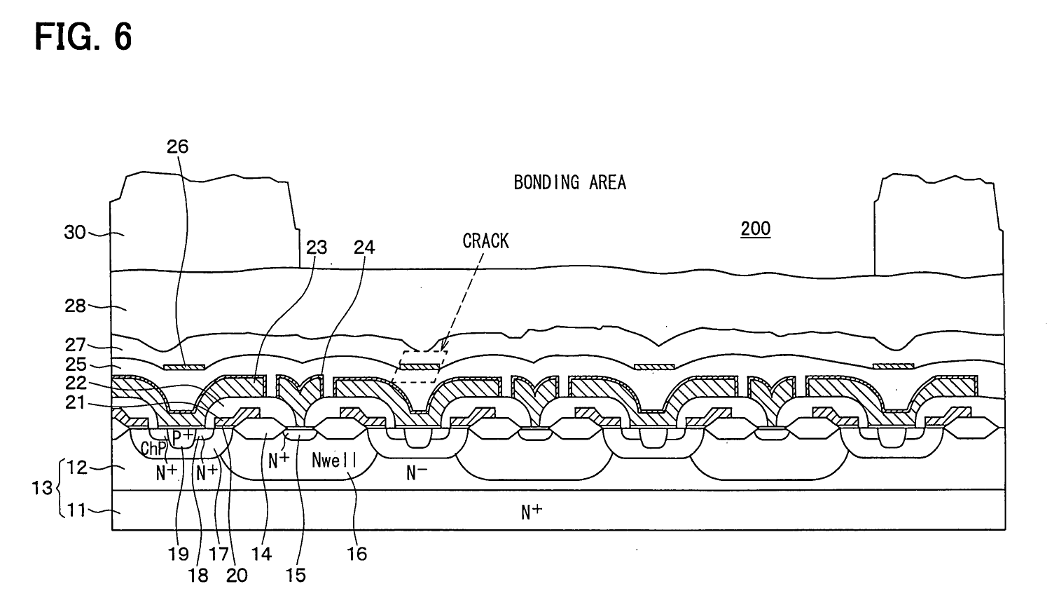

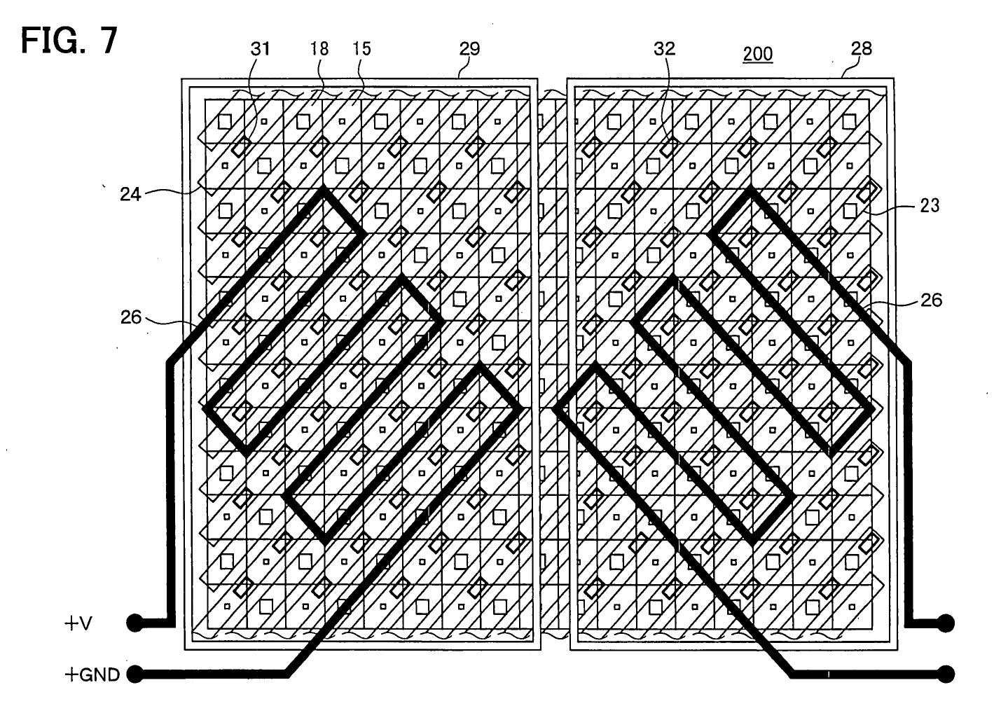

A semiconductor device 200 according to a second embodiment of the present invention is shown in FIGS. 6 and 7. The device 200 includes a Laterally Diffused Metal Oxide Semiconductor (LDMOS) element.

The LDMOS element is formed on a substrate 13. The substrate 13 is constructed by forming an N⁻-type layer 12 on an N⁺-type silicon substrate 11. A LOCOS (local oxidation of silicon) oxide film 14 is formed on the surface of the N⁻-type layer 12. An N⁺-type drain region 15 of high impurity concentration is formed in the surface of the N⁻-type layer 12 to contact with the LOCOS oxide film 14. An N-type well 16 is formed to surround the N⁺-type drain region 15 and extends under the LOCOS oxide film 14. In the N-type well 16, impurity concentration decreases with distance from the N⁺-type drain region 15.

A P-type base region 17 is formed on the surface of the N⁻-type layer 12. The P-type base region 17 is terminated near the edge of the LOCOS oxide film 14. An N⁺-type source region 18 is formed on the surface of the P-type base region 17 to be spaced from the LOCOS oxide film 14. A P⁺-type contact region 19 is formed on the surface of the P-type base region 17 to contact with the N⁺-type source region 18. The P⁺-type contact region 19 is formed on the opposite side of the N⁺-type drain region 15 across the N⁺-type source region 18 and extends under the N⁺-type source region 18. A gate insulating film 20 is formed on the surface of the P-type base region 17, which is located between the N⁺-type source region 18 and the N⁺-type drain region 15. A gate electrode 21 is disposed on the gate insulating film 20.

The surface region of the P⁺-type base region 17 is constructed as a channel region and the substrate 13 is constructed as an N-type drift region. Thus, the LDMOS element performs a MOS function.

A boron-doped phosphor-silicate glass (BPSG) film 22 is disposed to cover the gate electrode 21. A first aluminum source electrode 23 and a first aluminum drain electrode 24 are formed on the BPSG film 22 by a patterning method. The first aluminum source electrode 23 is connected to the N⁺-type source region 18 and the P⁺-type contact region 19 through contact holes formed in the BPSG film 22. Likewise, the first aluminum drain electrode 24 is connected to the N⁺-type drain region 15 through the contact holes.

A first TEOS film 25 covers the first aluminum source electrode 23 and the first aluminum drain electrode 24. A thin film resistor 26 is formed on the surface of the first TEOS film 25.

A second TEOS film 27 is disposed on the surfaces of the thin film resistor 26 and the first TEOS film 25. A second aluminum source electrode 28 and a second aluminum drain electrode 29 (shown in FIG. 7) are disposed on the second TEOS film 27.

A protective film 30 is disposed on the surfaces of the second aluminum source electrode 28 and the second aluminum drain electrode 29.

As shown in FIG. 7, the N⁺-type drain region 15 and the N⁺-type source region 18 are disposed in a matrix pattern. Cells of the matrix pattern of the N⁺-type drain region 15 and cells of the matrix pattern of the N⁺-type source region 18 are alternately arranged in row and column directions.

The first aluminum drain electrode 24 and the first aluminum source electrode 23 are disposed in a stripe pattern. Stripe lines of the first aluminum drain electrode 24 connected to the N⁺-type drain region 15 and stripe lines of the first aluminum source electrode 23 connected to the N⁺-type source region 18 are alternately arranged.

The stripe lines of the first aluminum drain electrode 24 are electrically connected to the second aluminum drain electrode 29 through via holes 31. The stripe lines of the first aluminum source electrode 23 are electrically connected to the second aluminum source electrode 28 through via holes 32.

The thin film resistor 26 includes first line portions and second line portions. The first line portions are in parallel with the stripe lines. The second line portions connect the first line portions with each other so that the thin film resistor 26 is constructed as single line. The thin film resistor 26 is disposed under the second aluminum source electrode 28 and the second aluminum drain electrode 29.

As described above, the device 200 has the thin film resistor 26 interposed between the first TEOS film 25 and the second TEOS film 27, i.e., between the interlayer insulation films. The thin film resistor 26 is used for the crack inspection in the same way as the thin film resister 5 of the device 100. The crack in the device 200 can be detected by measuring the resistance of the thin film resistor 26. Thus, the thin film resistor 26 enables the crack inspection to be conducted during various stages in the manufacturing process of the device 200.

The crack inspection can be conducted without disassembling the package or disconnecting the wiring, i.e., without destruction of the device 200. Therefore, not only a sampling inspection, but also a 100% inspection can be applied to the device 200. The quality of the device 200 increases accordingly.

Modifications

The embodiment described above may be modified in various ways.

The thin film resistor 5 may be formed in different shapes from the stripe pattern, as long as the resistance of the thin film resistor 5 changes at the time of occurrence of the crack. For example, the thin film resistor 5 may be formed in a solid pattern with extended width.

The thin film resistors 5, 26 may be used not only for the crack inspection but also for other applications. For example, the thin film resistors 5, 26 may be used as a resistor or a protective resistance element that serves as a component of an integrated circuit on which the device 100 or 200 is mounted.

The thin film resistors 5, 26 may be constructed not only as a single layer film resistor but also a multilayered film resistor. The multilayered film resistor can be constructed as single resistor by connecting each layer of the multilayered film resistor. Alternatively, the layers of the multilayered film resistor may be electrically isolated from each other to construct multiple independent resistors. In this case, by passing a current through the independent layers of the multilayered film resistor, it can be determined which layer the crack occurs in. As a result, the depth of the crack can be also detected.

The above embodiments can be applied to a semiconductor device using Flip Chip package or CSP (chip size package).

Such changes and modifications are to be understood as being within the scope of the present invention as defined by the appended claims.

What is claimed is:

1. A semiconductor device comprising:
a substrate;
a semiconductor element disposed on the substrate;
a first insulation film disposed on the substrate;
a second insulation film disposed on a surface of the first insulation film;
a thin film resistor disposed between the first and the second insulation films;
a first electrode pad disposed on one end of the thin film resistor; and
a second electrode pad disposed on the other end of the thin film resistor,
wherein
a predetermined voltage is applied to the thin film resistor using the first and the second electrode pads to pass an electric current through the thin film resistor, and
when a crack occurs in at least one of the first and the second insulation film, the thin film resistor is at least partially destroyed so that the amount of the current changes.

2. The device according to claim 1, wherein
the second electrode pad is electrically connected to a ground.

3. The device according to claim 1, wherein
the thin film resistor includes a plurality of line portions to be spaced from each other so that a stripe pattern appears on a surface of the thin film resistor,
the line portions are merged with each other at both ends of the line potions to connect the first and the second electrode pads, and
when a crack occurs in at least one of the first and the second insulation films, at least one of the line portions is disconnected.

4. The device according to claim 1, wherein
the resistance of the thin film resistor is determined based on the predetermined voltage applied to the thin film resistor and the current flowing through the thin film resistor, and
it is determined whether a crack occurs in at least one of the first and the second insulation films based on the resistance of the thin film resistor.

5. The device according to claim 1, wherein
the thin film resistor overlaps an area where the semiconductor element is disposed.

6. The device according to claim 1, wherein
the substrate has a wiring layer electrically connected to the semiconductor element, and
the thin film resistor is disposed over the wiring layer.

7. The device according to claim 1, wherein
the substrate has a wire bonding portion electrically connected to the semiconductor element, and
the thin film resistor is disposed under the wire bonding portion.

8. The device according to claim 1, wherein
the thin film resistor is disposed near a corner portion of the substrate.

9. The device according to claim 1, wherein
the thin film resistor has a thickness in a range between about 5 nanometers and 500 nanometers.

10. The device according to claim 1, wherein
the thin film resistor has a thickness in a range between about 5 nanometers and 50 nanometers.

11. The device according to claim 1, wherein
thin film resistor is made of aluminum, aluminum silicon, aluminum silicon copper, polysilicon, titanium, titanium nitride, tungsten silicide, titanium silicide, chromium, cupper, nickel, cobalt, or gold.

12. A semiconductor device comprising:
a substrate;
a semiconductor element disposed on the substrate;
a first insulation film disposed on the substrate;
a second insulation film disposed on the substrate;
a plurality of thin film resistors disposed between the first and the second insulation films and stacked together to provide a multilayered resistor;
a first electrode pad disposed on one end of multilayered resistor; and
a second electrode pad disposed on the other end of the multilayered resistor,
wherein
the thin film resistors are electrically isolated from each other,
a predetermined voltage is applied to each thin film resistor using the first and the second electrode pads to pass an electric current through the thin film resistors, and
when a crack occurs in at least one of the first and the second insulation films, the thin film resistors are at least partially destroyed so that the amount of the current flowing through the destroyed thin film resistors changes.

13. The device according to claim 12, wherein
the second electrode pad is electrically connected to a ground.

14. The device according to claim 12, wherein
the multilayered resistor includes a plurality of line portions to be spaced from each other so that a stripe pattern appears on a surface of the multilayered resistor,
the line portions are merged with each other at both ends of the line potions to connect the first and the second electrode pads, and
when a crack occurs in at least one of the first and the second insulation films, at least one of the line portions is disconnected.

15. The device according to claim 12, wherein
the multilayered resistor overlaps an area where the semiconductor element is disposed.

16. The device according to claim 12, wherein
the substrate has a wiring layer electrically connected to the semiconductor element, and
the multilayered resistor is disposed over the wiring layer.

17. The device according to claim 12, wherein
the substrate has a wire bonding portion electrically connected to the semiconductor element, and
the multilayered resistor is disposed under the wire bonding portion.

18. The device according to claim 12, wherein
the multilayered resistor is disposed near a corner portion of the substrate.

19. The device according to claim 12, wherein
the multilayered resistor has a thickness in a range between about 5 nanometers and 500 nanometers.
